(19) United States
(12) Patent Application Publication
(10) Pub. No.: US 2022/0223442 A1
(43) Pub. Date: Jul. 14, 2022

(54) SEMICONDUCTOR MANUFACTURING APPARATUS AND CONTROL METHOD THEREOF

(71) Applicant: Kioxia Corporation, Tokyo (JP)

(72) Inventor: Yuichi KURODA, Yokkaichi (JP)

(73) Assignee: Kioxia Corporation, Tokyo (JP)

(21) Appl. No.: 17/403,724

(22) Filed: Aug. 16, 2021

(30) Foreign Application Priority Data
Jan. 13, 2021 (JP) 2021-003289

(51) Int. Cl. H01L 21/67; H01L 21/66

(52) U.S. Cl. CPC H01L 21/67253; H01L 22/10; H01L 21/67017

(57) ABSTRACT

A semiconductor manufacturing apparatus includes: a reaction chamber; a pipe connected to the reaction chamber; a vacuum pump that has an intake port and an exhaust port, and in which the intake port or the exhaust port is connected to the pipe; a first acoustic sensor provided in the pipe; and a control device including a determination unit configured to determine clogging of the pipe based on a first output of the first acoustic sensor.

### CROSS-REFERENCE TO RELATED APPLICATION(S)

This application is based upon and claims the benefit of priority from Japanese Patent Application No. 2021-003289; filed Jan. 13, 2021; the entire contents of which are incorporated herein by reference.

### FIELD

Embodiments described herein relate generally to a semiconductor manufacturing apparatus and a control method thereof.

### BACKGROUND

For example, as a method of forming a high-quality film, there is a method of growing a film on a wafer (substrate) based on a chemical vapor deposition (CVD) method.

### DESCRIPTION OF THE DRAWINGS

FIG. 1 is a schematic view showing a semiconductor manufacturing apparatus according to at least one embodiment.

FIGS. 2A and 2B are schematic cross-sectional views showing a state of deposition of a deposit in a pipe according to at least one embodiment.

FIG. 3 is a schematic view showing an example of outputs of an acoustic sensor before and after cleaning an inside of the pipe in the semiconductor manufacturing apparatus according to at least one embodiment.

FIGS. 4A and 4B are schematic diagrams showing an example of how to attach the acoustic sensor according to at least one embodiment.

FIG. 5 is a schematic cross-sectional diagram showing another example of how to attach the acoustic sensor according to at least one embodiment.

FIG. 6 is a schematic cross-sectional diagram showing another example of how to attach the acoustic sensor according to at least one embodiment.

FIG. 7 is a flowchart showing a control method of the semiconductor manufacturing apparatus according to at least one embodiment.

### DETAILED DESCRIPTION

At least one embodiment provides a semiconductor manufacturing apparatus and a control method thereof that are capable of checking clogging of a pipe without stopping.

In general, according to at least one embodiment, a semiconductor manufacturing apparatus includes: a reaction chamber; a pipe connected to the reaction chamber; a vacuum pump that has an intake port and an exhaust port, and in which the intake port or the exhaust port is connected to the pipe; a first acoustic sensor provided in the pipe; and a control device (controller) including a determination unit configured to determine clogging of the pipe based on a first output of the first acoustic sensor.

According to at least one embodiment, a control method of a semiconductor manufacturing apparatus is a semiconductor manufacturing method using the semiconductor manufacturing apparatus. The semiconductor manufacturing apparatus includes: a reaction chamber; a pipe connected to the reaction chamber; a vacuum pump that has an intake port and an exhaust port, and in which the intake port or the exhaust port is connected to the pipe; and a first acoustic sensor provided in the pipe. The control method includes determining clogging of the pipe based on a first output of the first acoustic sensor.

An embodiment will be described below with reference to drawings. In the drawings, the same or similar locations are denoted by the same or similar reference numerals.

### Embodiment

According to at least one embodiment, a semiconductor manufacturing apparatus includes: a reaction chamber, a pipe connected to the reaction chamber, a vacuum pump that has an intake port and an exhaust port, and in which the intake port or the exhaust port is connected to the pipe; a first acoustic sensor provided in the pipe; and a control device (controller) including a determination unit configured to determine clogging of the pipe based on a first output of the first acoustic sensor.

According to at least one embodiment, a control method of a semiconductor manufacturing apparatus is a semiconductor manufacturing method using the semiconductor manufacturing apparatus. The semiconductor manufacturing apparatus includes: a reaction chamber; a pipe connected to the reaction chamber; a vacuum pump that has an intake port and an exhaust port, and in which the intake port or the exhaust port is connected to the pipe; and a first acoustic sensor provided in the pipe. The control method includes determining clogging of the pipe based on a first output of the first acoustic sensor.

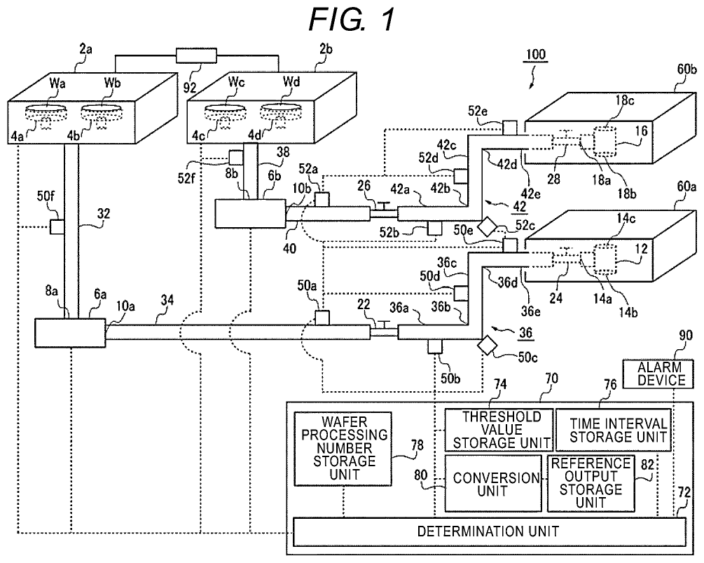

FIG. 1 is a schematic view of a semiconductor manufacturing apparatus 100 according to the embodiment.

The semiconductor manufacturing apparatus 100 includes a reaction chamber 2, a support portion 4, a vacuum pump 6, a three-way valve 12, a three-way valve 16, a valve 22, a valve 24, a valve 26, a valve 28, a pipe 32, a pipe 34, a pipe 36, a pipe 38, a pipe 40, a pipe 42, an acoustic sensor 50, an acoustic sensor 52, a detoxifying device 60, a control device 70 (controller), and an alarm device 90.

The control device 70 includes a determination unit 72, a threshold value storage unit 74, a time interval storage unit 76, a wafer processing number storage unit 78, a conversion information storage unit 80, and a reference output storage unit 82.

The semiconductor manufacturing apparatus 100 according to at least one embodiment is, for example, an apparatus that grows a film on a wafer W such as a silicon wafer using a CVD method.

FIG. 1 shows a reaction chamber 2a and a reaction chamber 2b as the reaction chamber 2. The growth of the film is performed in the reaction chamber 2. A process gas supply mechanism 92 is connected to the reaction chamber 2. The process gas supply mechanism 92 includes, for example, a gas generation unit, a gas cylinder, a pipe, a control valve, and a flow rate control mechanism such as a mass flow controller, which are not shown. The process gas supply mechanism supplies process gas into the reaction chamber 2. The process gas is, for example, Tetraethyl Orthosilicate (TEOS) gas. The semiconductor manufacturing apparatus 100 forms a TEOS film (SiO₂ film) on the surface of the wafer W based on the CVD method using the process gas. In FIG. 1, the process gas supply mechanism 92 alone is connected to both the reaction chamber 2a and the reaction chamber 2b. However, an individual process gas supply mechanism 92 may be connected to each of the reaction chamber 2a and the reaction chamber 2b.

In the reaction chamber 2, a support portion 4 on which the wafer W can be placed and which rotates the wafer W in a circumferential direction of the wafer W is provided. In FIG. 1, a support portion 4a and a support portion 4b are provided in the reaction chamber 2a. A support portion 4c and a support portion 4d are provided in the reaction chamber 2b. As the support portion 4, for example, a holder that has an opening portion at a center and supports a substrate at a peripheral edge is used. As the support portion 4, a susceptor having no opening portion may be used.

Although the wafer W is, for example, a silicon wafer, the wafer may be a sapphire wafer or the like. In FIG. 1, a wafer Wₐ is provided on the support portion 4a, a wafer W_{b} is provided on the support portion 4b, a wafer W_{c} is provided on the support portion 4c, and a wafer W_{d} is provided on the support portion 4d.

The number of reaction chamber 2, a type of process gas, a type and the number of the support portions 4, and a type and the number of the wafers W in the semiconductor manufacturing apparatus 100 are not limited to those described above.

FIG. 1 shows a vacuum pump 6a and a vacuum pump 6b as the vacuum pump 6. The vacuum pump 6a includes an intake port 8a and an exhaust port 10a. The vacuum pump 6b includes an intake port 8b and an exhaust port 10b. The vacuum pump 6 is an exhaust system including, for example, a dry pump or a pressure gauge.

The pipe 32 is connected to the reaction chamber 2a and the intake port 8a. The pipe 34 is connected to the exhaust port 10a. The vacuum pump 6a intakes excess process gas and reaction byproducts in the reaction chamber 2a from the intake port 8a via the pipe 32. Then, the vacuum pump 6a exhausts the excess process gas and the reaction byproducts from the exhaust port 10a to the pipe 34.

The pipe 34 is connected to the valve 22. Further, the pipe 34 is connected to the pipe 36 via the valve 22. The pipe 36 includes a pipe part 36a, a pipe part 36c, a pipe part 36e, a curved portion 36b that connects the pipe part 36a and the pipe part 36c, and a curved portion 36d that connects the pipe part 36c and the pipe part 36e. The curved portion 36b and the curved portion 36d are, for example, elbows of pipes. The valve 22 is, for example, a ball valve or a butterfly valve.

The pipe 38 is connected to the reaction chamber 2b and the intake port 8b. The pipe 40 is connected to the exhaust port 10b. The vacuum pump 6b intakes excess process gas and reaction byproducts in the reaction chamber 2b from the intake port 8b via the pipe 38. Then, the vacuum pump 6a exhausts the excess process gas and the reaction byproducts from the exhaust port 10b to the pipe 40.

The pipe 40 is connected to the valve 26. Further, the pipe 40 is connected to the pipe 42 via the valve 26. The pipe 42 includes a pipe part 42a, a pipe part 42c, a pipe part 42e, a curved portion 42b that connects the pipe part 42a and the pipe part 42c, and a curved portion 42d that connects the pipe part 42c and the pipe part 42e. The curved portion 42b and the curved portion 42d are, for example, elbows of pipes. The valve 26 is, for example, a ball valve or a butterfly valve.

The number of the vacuum pumps 6, a form of the pipes, and a form of the valves in the semiconductor manufacturing apparatus 100 are not limited to those described above.

The detoxifying device 60 detoxifies toxic gas and combustible gas that are discharged from the reaction chamber 2. The detoxifying device 60 is, for example, a scrubber. FIG. 1 shows a detoxifying device 60a and a detoxifying device 60b as the detoxifying device 60.

The detoxifying device 60a is connected to the pipe part 36e. The pipe part 36e is connected to a port 14a of the three-way valve 12 via the valve 24 in the detoxifying device 60a. The valve 24 is, for example, a ball valve or a butterfly valve. A port 14b of the three-way valve 12 is connected to a combustion furnace (not shown) in the detoxifying device 60a. In the combustion furnace (not shown), the toxic gas and the combustible gas are detoxified. The port 14c of the three-way valve 12 is connected to, for example, a bypass line (not shown). Then, the toxic gas or the combustible gas detoxified by the combustion furnace is discharged through the bypass line (not shown).

The detoxifying device 60b is connected to the pipe part 42e. The pipe part 42e is connected to a port 18a of the three-way valve 16 via the valve 28 in the detoxifying device 60b. The valve 28 is, for example, a ball valve or a butterfly valve. A port 18b of the three-way valve 16 is connected to a combustion furnace (not shown) in the detoxifying device 60b. In the combustion furnace (not shown), the toxic gas and the combustible gas are detoxified. The port 18c of the three-way valve 16 is connected to, for example, a bypass line (not shown). Then, the toxic gas or the combustible gas detoxified by the combustion furnace is discharged through the bypass line (not shown).

The acoustic sensor 50 is provided outside the pipe 32, the pipe 34, or the pipe 36. The acoustic sensor 50 is, for example, an acoustic emission (AE) sensor. The acoustic sensor 50 measures vibration of the pipe 32, the pipe 34, or the pipe 36. Then, the acoustic sensor 50 outputs a result of the measured vibration to an outside of the acoustic sensor 50. The output is an example of the first output or a second output.

FIG. 1 shows an acoustic sensor 50a, an acoustic sensor 50b, an acoustic sensor 50c, an acoustic sensor 50d, an acoustic sensor 50e, and an acoustic sensor 50f as the acoustic sensor 50. The acoustic sensor 50a is provided, for example, on an upper side of the pipe 34. The acoustic sensor 50b is provided, for example, on a lower side of the pipe part 36a. The acoustic sensor 50c is provided, for example, on a lower side of the curved portion 36b. The acoustic sensor 50d is provided, for example, on a side surface of the pipe part 36c. The acoustic sensor 50e is provided, for example, on an upper side of the pipe part 36e. The acoustic sensor 50f is provided, for example, on a side surface of the pipe 32.

The acoustic sensor 52 is provided outside the pipe 38, the pipe 40, or the pipe 42. The acoustic sensor 52 is, for example, an acoustic emission (AE) sensor. The acoustic sensor 52 measures vibration of the pipe 38, the pipe 40, or the pipe 42. Then, the acoustic sensor 52 outputs a result of the measured vibration to an outside of the acoustic sensor 52. The output is an example of the first output or the second output.

FIG. 1 shows an acoustic sensor 52a, an acoustic sensor 52b, an acoustic sensor 52c, an acoustic sensor 52d, an acoustic sensor 52e, and an acoustic sensor 52f as the acoustic sensor 52. The acoustic sensor 52a is provided, for example, on an upper side of the pipe 40. The acoustic sensor 52b is provided, for example, on a lower side of the pipe part 42a. The acoustic sensor 52c is provided, for example, on a lower side of the curved portion 42b. The acoustic sensor 52d is provided, for example, on a side surface of the pipe part 42c. The acoustic sensor 52e is provided, for example, on an upper side of the pipe part 42e. The acoustic sensor 52f is provided, for example, on a side surface of the pipe 38.

The acoustic sensor 50 is an example of the first acoustic sensor or a second acoustic sensor. The acoustic sensor 52 is an example of the first acoustic sensor or the second acoustic sensor.

The acoustic sensor 50 and the acoustic sensor 52 preferably measure a sound having a frequency of 100 kHz or more and 200 kHz or less.

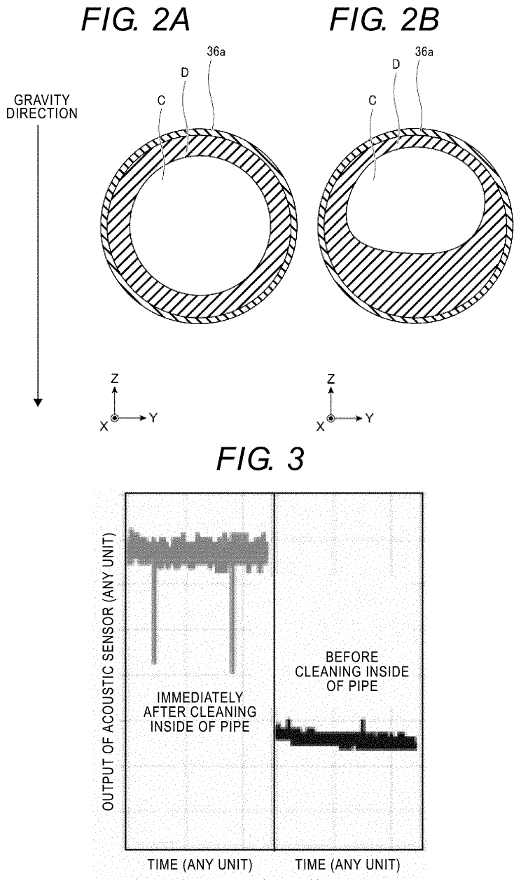

FIGS. 2A and 2B is a schematic cross-sectional view showing a state of deposition of a deposit D in a pipe according to the embodiment. Arrows in FIGS. 2A and 2B indicate a positional relationship between a gravity direction and the deposit D in the pipe part 36a.

In FIG. 2A, the deposit D is uniformly deposited on an inner wall of the pipe part 36a. Therefore, a cross-sectional shape of a cavity C is circular. In FIG. 2B, the deposit D is deposited inside the lower pipe part 36a. One of the reasons for such deposition is that the deposit D is more likely to be deposited downward due to gravity. In the pipe 34 and the pipe part 36a that are closer to the vacuum pump 6a with respect to the curved portion 36b, and in the pipe 40 and the pipe part 42a that are closer to the vacuum pump 6b with respect to the curved portion 42b, since the excess process gas is less likely to smoothly flow through the curved portion 36b or the curved portion 42b, the excess process gas is likely to stay inside. Therefore, in addition to an effect of gravity, the deposit D is more likely to be deposited downward.

FIG. 3 is a schematic view showing an example of outputs of the acoustic sensor before and after cleaning an inside of the pipe in the semiconductor manufacturing apparatus 100 according to at least one embodiment. The output of the acoustic sensor before the cleaning of the inside of the pipe is lower than the output of the acoustic sensor immediately after the cleaning of the inside of the pipe. The above indicates that a vibration of the pipe tends to decrease as the deposit D is deposited in the pipe. The above also indicates that a degree of deposition of the deposit D inside the pipe can be evaluated by evaluating the vibration of the pipe using the acoustic sensor. A reason why such evaluation is possible is considered to be that, when the deposit D is deposited in the pipe, molecules of the excess process gas flowing through the pipe do not directly collide with an inner wall of the pipe, and thus the vibration of the pipe is reduced.

For example, when the deposit D is deposited in the pipe, it is considered that the deposit D vibrates together with the pipe. In a state in which the deposit D is deposited in the pipe, in order to vibrate the pipe by the same degree as in a state in which the deposit D is not deposited in the pipe, it is considered that a larger vibration energy is required. Therefore, it is considered that a vibration of the pipe tends to decrease as the deposit D is deposited in the pipe.

According to the above, it is considered that the degree of deposition of the deposit D inside the pipe can be evaluated by evaluating the vibration of the pipe using the acoustic sensor.

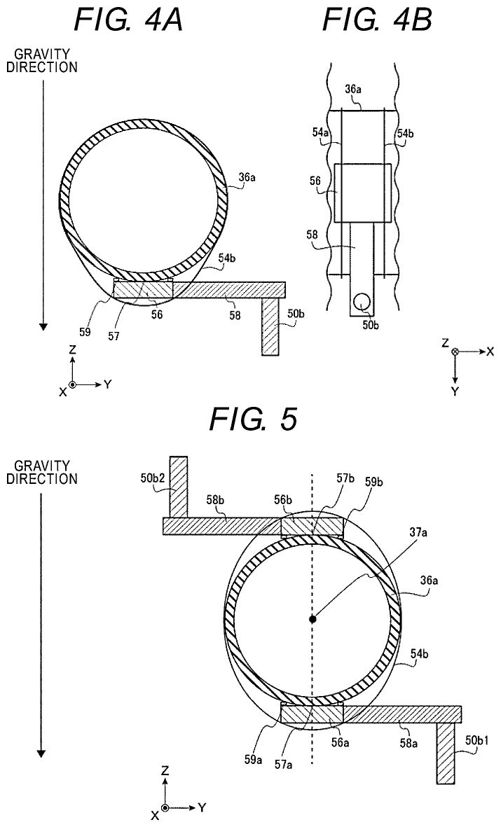

FIGS. 4A and 4B are schematic diagrams showing an example of how to attach the acoustic sensor according to at least one embodiment. In FIGS. 4A and 4B, a Z direction is a direction opposite to the gravity direction. In FIGS. 4A and 4B, an X direction is a direction that perpendicularly intersects the Z direction. The X direction is a direction in which the pipe part 36a extends. In FIGS. 4A and 4B, the Y direction is a direction that perpendicularly intersects the X direction and the Z direction. FIG. 4A is a schematic cross-sectional diagram showing the example of how to attach the acoustic sensor according to the embodiment in a YZ plane. In FIG. 4A, a wire 54b is also shown. FIG. 4B is a schematic diagram showing the example of how to attach the acoustic sensor according to the embodiment in an XY plane. For example, as the acoustic sensor 50b in FIG. 4A, providing the acoustic sensor 50b on the lower side or a lower surface of the pipe part 36a is an example of a preferred aspect.

The acoustic sensor 50b is fixed to a lower surface of a plate 58 using, for example, a screw (not shown). A plate 56 and a plate 58 are fixed to each other using, for example, screws (not shown). The plate 56 and the plate 58 are, for example, metal plates. The plate member 56 is attached to the pipe part 36a using, for example, a wire 54a and the wire 54b. Further, the plate 56 and the pipe part 36a are in contact with each other at a contact portion 57. A fixing portion 59 fixes the plate member 56 such that the plate member 56 does not slip on a surface of the pipe part 36a. In this manner, the acoustic sensor 50b is provided at the contact portion 57 of the pipe part 36a via the plate member 56 and the plate member 58. The contact portion 57 is a part where a lower surface of the pipe part 36a and the plate 56 are in contact with each other.

FIG. 5 is a schematic cross-sectional diagram showing another example of how to attach the acoustic sensor according to the embodiment. In FIG. 5, a wire 54b is also shown. It is an example of a preferred aspect that an acoustic sensor 50b₁ is provided on the lower side or the lower surface of the pipe part 36a, and an acoustic sensor 50b₂ is provided on an upper side or an upper surface of the pipe part 36a.

In FIG. 5, the acoustic sensor 50b₁ is fixed to a lower surface of a plate 58a using, for example, a screw (not shown). The plate 56a and the plate 58a are fixed to each other using, for example, screws (not shown). The plate 56a and the plate 58a are, for example, metal plates. The plate 56a is attached to the pipe part 36a using, for example, the wire 54b. The plate 56a and the pipe part 36a are in contact with each other at a contact portion 57a. A fixing portion 59a fixes the plate member 56a such that the plate member 56a does not slip on the surface of the pipe part 36a. In this manner, the acoustic sensor 50b₁ is provided at the contact portion 57a of the pipe part 36a via the plate member 56a and the plate member 58a. The contact portion 57a is a part where the lower surface of the pipe part 36a and the plate 56a are in contact with each other. Therefore, in an aspect shown in FIG. 5, the acoustic sensor 50b₁ is provided on the lower side or the lower surface of the pipe part 36a.

In FIG. 5, the acoustic sensor 50b₂ is fixed to an upper surface of a plate 58b using, for example, a screw (not shown). A plate 56b and the plate 58b are fixed to each other using, for example, screws (not shown). The plate 56b and the plate 58b are, for example, metal plates. The plate 56b is attached to the pipe part 36a using, for example, the wire 54b. The plate 56b and the pipe part 36a are in contact with each other at a contact portion 57b. A fixing portion 59b fixes the plate member 56b such that the plate member 56b does not slip on the surface of the pipe part 36a. In this manner, the acoustic sensor 50b₂ is provided at the contact portion 57b of the pipe part 36a via the plate member 56b and the plate member 58b. The contact portion 57b is a part where the upper surface of the pipe part 36a and the plate 56b are in contact with each other. Therefore, in the aspect shown in FIG. 5, the acoustic sensor 50b₂ is provided on the upper side or the upper surface of the pipe part 36a.

In FIG. 5, the contact portion 57a and the contact portion 57b are provided at positions facing each other. In other words, both the contact portion 57a and the contact portion 57b pass through a straight line passing through a center 37a of the pipe, which is indicated by a dotted line in FIG. 5.

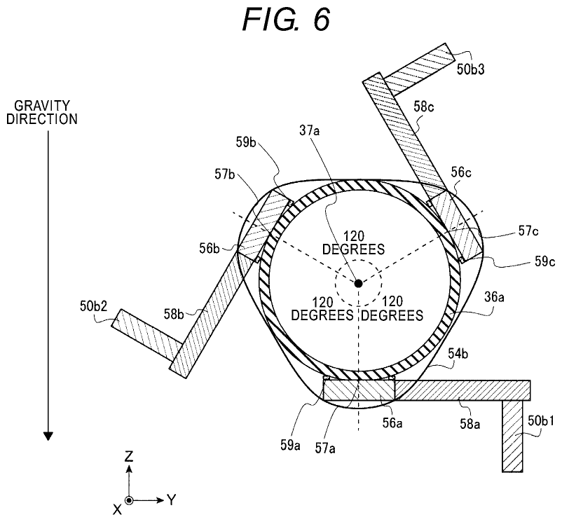

FIG. 6 is a schematic cross-sectional diagram showing another example of how to attach the acoustic sensor according to the embodiment. In FIG. 6, the wire 54b is also shown. As shown in FIG. 6, it is an example of a preferred aspect that the acoustic sensor 50b₁ is provided on the lower side or the lower surface of the pipe part 36a, and the acoustic sensor 50b₂ and an acoustic sensor 50b₃ are disposed around the pipe part 36a in a manner of being separated from the acoustic sensor 50b₁ by 120 degrees.

In FIG. 6, the acoustic sensor 50b₁ is provided on the lower side or the lower surface of the pipe part 36a. The acoustic sensor 50b₂ is provided at a part deviated clockwise by 120 degrees in a plane perpendicular to the direction (X direction), in which the pipe part 36a extends, from a part of the pipe part 36a where the acoustic sensor 50b₁ is provided. The acoustic sensor 50b₃ is provided at a part deviated counterclockwise by 120 degrees in the plane perpendicular to the direction (X direction), in which the pipe part 36a extends, from the part of the pipe part 36a where the acoustic sensor 50b₁ is provided. In other words, the acoustic sensor 50b₃ is provided at a part deviated clockwise by 120 degrees in the plane perpendicular to the direction (X direction), in which the pipe part 36a extends, from a part of the pipe part 36a where the acoustic sensor 50b₂ is provided.

For example, among the acoustic sensor 50a, the acoustic sensor 50b, the acoustic sensor 50d, and the acoustic sensor 50e, there is a high chance that the acoustic sensor 50b can obtain an output corresponding to the deposit D by the largest deposition amount. This is because the excess process gas is likely to remain inside since the pipe part 36a in which the acoustic sensor 50b is provided is located at a location closer to the reaction chamber 2a with respect to the curved portion 36b and is located at a location closer to the curved portion 36b.

There is a high chance that the acoustic sensor 50d can obtain an output corresponding to the deposit D by a next largest deposition amount after the acoustic sensor 50b. This is because the excess process gas is likely to remain inside since the pipe part 36c is located at a location closer to the reaction chamber 2a with respect to the curved portion 36d and is located at a location closer to the curved portion 36d. However, a large amount of the deposit D is deposited inside the pipe part 36a in which the acoustic sensor 50b is provided, and then the process gas passes through the pipe part 36c. Therefore, it is considered that an amount of the deposit D in the pipe part 36c provided with the acoustic sensor 50d is smaller than an amount of the deposit D in the pipe part 36a provided with the acoustic sensor 50b by the amount of the deposit D deposited in the pipe part 36a.

There is a high chance that the acoustic sensor 50a can obtain an output corresponding to the deposit D by a next largest deposition amount after the acoustic sensor 50d. This is because the pipe 34 in which the acoustic sensor 50a is provided is closer to the vacuum pump 6a with respect to the pipe part 36e in which the acoustic sensor 50e is provided, and thus it is considered that a gas containing a larger amount of reaction byproducts as the deposit D passes through the pipe 34.

For the same reason, among the acoustic sensor 52a, the acoustic sensor 52b, the acoustic sensor 52d, and the acoustic sensor 52e, there is a high chance that the acoustic sensor 52b can obtain the output corresponding to the deposit D by the largest deposition amount. There is a high chance that the acoustic sensor 52d can obtain an output corresponding to the deposit D by a next largest deposition amount after the acoustic sensor 52b. There is a high chance that the acoustic sensor 52a can obtain an output corresponding to the deposit D by a next largest deposition amount after the acoustic sensor 52d.

When the deposit D is deposited inside the pipe 34, the pipe 34 is removed between the exhaust port 10a and the valve 22, and the inside of the pipe 34 are cleaned.

When the deposit D is deposited inside the pipe 36, the pipe 36 is removed between the valve 22 and the detoxifying device 60a, and the inside of the pipe 36 is cleaned.

When the deposit D is deposited inside the pipe 40, the pipe 40 is removed between the exhaust port 10b and the valve 26, and the inside of the pipe 40 is cleaned.

When the deposit D is deposited inside the pipe 42, the pipe 42 is removed between the valve 26 and the detoxifying device 60b, and the inside of the pipe 42 is cleaned.

The determination unit 72 determines clogging of the pipe based on the output of the acoustic sensor 50 or the acoustic sensor 52.

When the determination unit 72 determines that “the pipe is clogged” or makes other determinations, for example, the control device 70 or the determination unit 72 can stop a manufacturing process performed in the reaction chamber 2 or the vacuum pump 6.

The threshold value storage unit 74 stores a threshold value for determining the clogging of the pipe. Then, the determination unit 72 determines the clogging of the pipe based on the threshold value.

The conversion information storage unit 80 has conversion information for converting the output of the acoustic sensor into a pipe clogging amount. Then, the determination unit 72 determines the clogging of the pipe based on the converted pipe clogging amount. Here, the conversion can be executed by, for example, the determination unit 72. The conversion may not be executed.

For example, the conversion information storage unit 80 preferably has a plurality of pieces of conversion information. Here, the plurality of pieces of conversion information are prepared, for example, for each manufacturing process performed in the reaction chamber 2. Then, for example, based on the manufacturing process described above, the determination unit 72 can appropriately use the corresponding conversion information among the plurality of conversion information to apply the conversion information to each of the plurality of acoustic sensors 50, each of the plurality of acoustic sensors 52, or each of the acoustic sensor 50 and the acoustic sensor 52, and can determine the clogging of the pipe. For example, when the configuration of the film formed on the wafer W in the reaction chamber 2 is different, it can be considered that the manufacturing process performed in the reaction chamber 2 is different. Even when an exhaust amount of the vacuum pump 6 is different, it is considered that a way of accumulation of the deposit D is changed and away of clogging of the pipe is different, and thus different conversion information can be used. The above description is an example of “the conversion information storage unit has a plurality of pieces of conversion information used for each manufacturing process, and determines which of the plurality of pieces of conversion information is to be used based on the manufacturing process”.

The reference output storage unit 82 stores a reference output of an acoustic sensor provided in a pipe having no clogging. For example, the output of the acoustic sensor immediately after the cleaning of the inside of the pipe shown in FIG. 3 is stored in the reference output storage unit 82 as the reference output. In this case, the determination unit 72 can determine the clogging of the pipe based on a difference between the output of the acoustic sensor and the reference output. The reference output storage unit 82 may be omitted.

The acoustic sensor 50 and the acoustic sensor 52 preferably execute output at predetermined time intervals. The predetermined time interval is stored in the time interval storage unit 76.

The wafer processing number storage unit 78 stores the number of wafers W processed in the reaction chamber 2a and the reaction chamber 2b. In this case, the determination unit 72 can determine the clogging of the pipe based on the number of the wafers W.

For example, it is preferable that the determination unit 72 issues an alarm using the alarm device 90 based on the outputs of the acoustic sensor 50 or the acoustic sensor 52. Here, the determination unit 72 may issue an alarm using the alarm device 90 based on the output of one acoustic sensor 50 or acoustic sensor 52. For example, the determination unit 72 may issue an alarm based on outputs of a plurality of acoustic sensors 50 or acoustic sensors 52. For example, a case is considered in which the semiconductor manufacturing apparatus 100 includes a total of four acoustic sensors 50 or acoustic sensors 52. For example, when the number of the acoustic sensors 50 or the acoustic sensors 52 that issue an alarm is zero, it is determined that a pipe state is a state of “normal”, and the determination unit 72 may not issue an alarm using the alarm device 90. For example, when the number of the acoustic sensors 50 or the acoustic sensors 52 that issue an alarm is two, it is determined that the pipe state is a state of “caution”, and the determination unit 72 may issue an alarm on the state of “caution” using the alarm device 90. For example, when the number of the acoustic sensors 50 or the acoustic sensors 52 that issue an alarm is four, it is determined that the pipe state is a state in which a “replacement alarm” is to be issued, and the determination unit 72 may issue an alarm on the state using the alarm device 90. For example, the determination unit 72 may control and issue different types of alarms such as the “normal”, the “caution”, and “replacement information” together with an increase in the number of wafers W stored in the wafer processing number storage unit 78 using the alarm device 90. The above aspect is an example of “further including a second acoustic sensor and an alarm device, in which the determination unit issues an alarm using the alarm device based on the first output and the second output of the second acoustic sensor”. The alarm device 90 is, for example, a chime, a siren, a lamp, or a monitor such as a liquid crystal monitor.

The control device 70 and the determination unit 72 are, for example, electronic circuits. The control device 70 and the determination unit 72 are, for example, computers formed by a combination of hardware such as an arithmetic circuit and software such as a program.

The threshold value storage unit 74, the time interval storage unit 76, the wafer processing number storage unit 78, the conversion information storage unit 80, and the reference output storage unit 82 are, for example, semiconductor memories or hard disks.

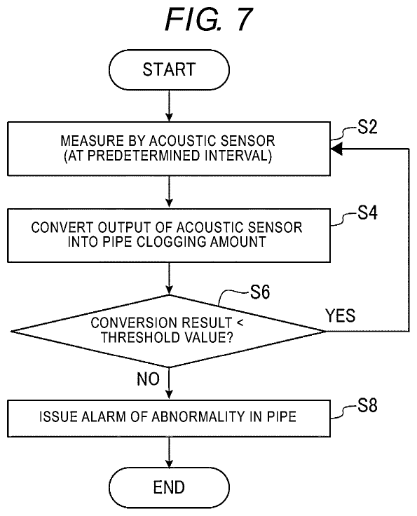

FIG. 7 is a flowchart showing a control method of the semiconductor manufacturing apparatus 100 according to the embodiment.

First, the wafer W is placed on the support portion 4 in the reaction chamber 2. Next, process gas is introduced into the reaction chamber 2 using the process gas supply mechanism 92 to form a film on the wafer W. The excess process gas and the reaction byproducts are exhausted by the vacuum pump 6.

Next, for example, the determination unit 72 measures the vibration caused by the process gas flowing inside the pipe using the output of the acoustic sensor 50 or the output of the acoustic sensor 52. The output and the measurement may be executed at predetermined time intervals using, for example, time stored in the time interval storage unit 76 (S2).

Next, for example, the determination unit 72 converts the output of the acoustic sensor 50 or the output of the acoustic sensor 52 into the pipe clogging amount using the conversion information stored in the conversion information storage unit 80 (S4). The conversion may not be executed.

Next, the determination unit 72 determines the clogging of the pipe, for example, based on an obtained conversion result (pipe clogging amount) and the threshold value stored in the threshold value storage unit 74. For example, the determination unit 72 determines whether the pipe clogging amount is smaller than the threshold value (S6).

When the pipe clogging amount is smaller than the threshold value, for example, the determination unit 72 further executes measurement by the acoustic sensor (S2). On the other hand, when the pipe clogging amount is equal to or greater than the threshold value, for example, the determination unit 72 issues an alarm that “there is an abnormality in the pipe (there is a certain amount or more of clogging in the pipe)” using the alarm device 90.

Next, functions and effects of the semiconductor manufacturing apparatus 100 and the control method of the semiconductor manufacturing apparatus 100 according to the embodiment will be described.

In the pipe connected to the semiconductor manufacturing apparatus 100, the excess process gas, the reaction byproducts, and the like react inside the pipe and are deposited as the deposits D inside the pipe. In related arts, during an operation of the semiconductor manufacturing apparatus 100, it is difficult to check the amount of the deposit D inside the pipe, and it is necessary to wait until replacement of the pipe or cleaning of the pipe is performed. Therefore, in related arts, a certain time interval is determined, and the pipe is always mechanically replaced at the time interval. However, in this case, the pipe may be replaced even though the inside of the pipe is not fairly clogged. Even though time is shorter than the time interval, the pipe may be clogged.

Therefore, according to at least one embodiment, the semiconductor manufacturing apparatus includes the reaction chamber 2, the pipe connected to the reaction chamber 2, the vacuum pump 6 that has the intake port 8 and the exhaust port 10, and in which the intake port 8 or the exhaust port 10 is connected to the pipe, the acoustic sensor provided in the pipe, and the control device 70 including the determination unit 72 that determines clogging of the pipe based on the output of the acoustic sensor.

As described above, when the deposit D is deposited in the pipe, molecules of the excess process gas flowing through the pipe do not directly collide with the inner wall of the pipe, and thus the vibration of the pipe is reduced. Therefore, the clogging of the pipe can be determined based on the output of the acoustic sensor 50 or the acoustic sensor 52. In this case, the clogging of the pipe can be checked without visually checking the inside of the pipe. Therefore, the clogging of the pipe can be checked without reducing an operation rate of the semiconductor manufacturing apparatus wastefully by, for example, stopping the semiconductor manufacturing apparatus and replacing the pipe.

For example, it is considered that the output of the acoustic sensor decreases with the clogging of the pipe. Therefore, for example, the determination unit 72 can determine, using the threshold value stored in the threshold value storage unit 74, that the cleaning of the pipe is necessary when the output of the acoustic sensor is small to what degree.

A correlation relationship between the degree of the clogging of the pipe due to the deposit D or the like and the output of the acoustic sensor can be measured in advance, and the correlation relationship can be stored in the conversion information storage unit 80 as the conversion information. Accordingly, it is possible to monitor the degree of the clogging of the pipe in more detail.

It is preferable that a plurality of pieces of the conversion information is used for each manufacturing process, and which of the plurality of pieces of conversion information is to be used is determined based on the manufacturing process. When the configuration of the film formed on the wafer W in the reaction chamber 2 is different, or the exhaust amount of the vacuum pump 6 is different, it is considered that the way of the accumulation of the deposit D is changed and the way of the clogging of the pipe is different. Therefore, it is possible to monitor the degree of the clogging of the pipe in more detail.

It is preferable that the reference output storage unit 82 stores the reference output of the acoustic sensor provided in the pipe having no clogging. Since it is easy to compare the output of the pipe having no clogging with the reference output, it is possible to monitor the degree of the clogging of the pipe in more detail.

It is preferable that when the determination unit 72 determines that “the pipe is clogged” or makes other determinations, for example, the control device 70 or the determination unit 72 stops the manufacturing process performed in the reaction chamber 2 or the vacuum pump 6. When the pipe is clogged, if manufacturing of the semiconductor is continued as it is, rupture or the like of the pipe may occur, which is dangerous. This risk can be avoided by stopping the manufacturing process performed in the reaction chamber 2 or the vacuum pump 6.

It is preferable that the semiconductor manufacturing apparatus further includes the second acoustic sensor and the alarm device. The determination unit issues the alarm using the alarm device based on the first output and the second output of the second acoustic sensor. The above is because a level of how to issue the alarm can be classified, and an operator of the semiconductor manufacturing apparatus can determine the clogging of the pipe in more detail.

For example, it is preferable to determine, based on the manufacturing process, which of the plurality of pieces of conversion information is used for each of the plurality of acoustic sensors 50, each of the plurality of acoustic sensors 52, or each of the acoustic sensor 50 and the acoustic sensor 52. In a case in which the configuration of the film formed on the wafer W in the reaction chamber 2 is different, in a case in which the exhaust amount of the vacuum pump 6 is different, or in other cases, it is considered that the way of the accumulation of the deposit D is changed and the way of the clogging of the pipe is different, and thus it is possible to monitor the degree of the clogging of the pipe in more detail.

The acoustic sensor 50 and the acoustic sensor 52 preferably measure the sound having the frequency of 100 kHz or more and 200 kHz or less. The above is because it is considered that the clogging of the pipe cannot be evaluated with a high SN ratio since the sound having a frequency of less than 100 kHz is considered to include a large amount of sound from another semiconductor manufacturing apparatus or the like provided around the semiconductor manufacturing apparatus 100. A sound having a frequency higher than 200 kHz has an excessively high frequency and is difficult to be measured.

It is preferable that the semiconductor manufacturing apparatus further includes the wafer processing number storage unit 78 that stores the number of wafers processed in the reaction chamber 2, and the determination unit 72 further determines the clogging based on the number of wafers. It is considered that there is a positive correlation relationship between the number of processed wafers and the clogging of the pipe. Therefore, by utilizing the number of processed wafers, it is possible to monitor the degree of the clogging of the pipe in more detail.

The acoustic sensor 50 and the acoustic sensor 52 preferably execute output at predetermined time intervals. This is because the clogging of the pipe can be prevented from being missed by executing the output at the predetermined time intervals.

For example, as in the acoustic sensor 50b in FIG. 4A, providing the acoustic sensor 50b on the lower side or the lower surface of the pipe part 36a is preferred. The above is because, when the deposit D is deposited as shown in FIG. 2B, the degree of deposition of the deposit D on the lower side in the pipe part 36a, in which the way of the deposition of the deposit D is larger, can be evaluated more favorably.

For example, as shown in FIG. 5, the acoustic sensor 50b₁ is provided on the lower side or the lower surface of the pipe part 36a, and the acoustic sensor 50b₂ is provided on the upper side or the upper surface of the pipe part 36a. When the deposit D is deposited as shown in FIG. 2B, the degree of deposition of the deposit D on the lower side in the pipe part 36a, in which the way of the deposition of the deposit D is larger, can be evaluated using the acoustic sensor 50b₁. The degree of deposition of the deposit D on the upper side in the pipe part 36a, in which the way of the deposition of the deposit D is smaller, can be evaluated using the acoustic sensor 50b₂. Accordingly, the degree of deposition of the deposit D can be evaluated on both the lower side and the upper side in the pipe part 36a.

As shown in FIG. 6, it is preferable that the acoustic sensor 50b₁ is provided on the lower side or the lower surface of the pipe part 36a, and the acoustic sensor 50b₂ and the acoustic sensor 50b₃ are disposed around the pipe part 36a in the manner of being separated from the acoustic sensor 50b₁ by 120 degrees. For example, it is considered that the deposit D may be unevenly deposited in the upper portion in the pipe part 36a. In this case, the degree of non-uniform deposition of the deposit D can be evaluated using the acoustic sensor 50b₂ and the acoustic sensor 50b₃.

According to the semiconductor manufacturing apparatus and the control method of the semiconductor manufacturing apparatus according to the embodiment, it is possible to provide the semiconductor manufacturing apparatus and the control method of the semiconductor manufacturing apparatus that are capable of checking the clogging of the pipe without stopping.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor manufacturing apparatus, comprising:
a reaction chamber;
a pipe connected to the reaction chamber;
a vacuum pump having an intake port and an exhaust port, wherein the intake port or the exhaust port is connected to the pipe;
a first acoustic sensor disposed in the pipe; and
a controller configured to determine clogging of the pipe based on a first output of the first acoustic sensor.

2. The semiconductor manufacturing apparatus according to claim 1, wherein
the controller includes a threshold value storage that stores a threshold value, and
the controller is configured to determine the clogging of the pipe based on the threshold value.

3. The semiconductor manufacturing apparatus according to claim 2, wherein
the controller further includes a conversion information storage having conversion information for converting the first output into a pipe clogging amount, and
the controller is configured to determine whether the pipe clogging amount meets the threshold value.

4. The semiconductor manufacturing apparatus according to claim 3, wherein
the conversion information storage has a plurality of pieces of the conversion information used for each manufacturing process, and
the controller is configured to determine which of the plurality of pieces of conversion information to use based on the manufacturing process.

5. The semiconductor manufacturing apparatus according to claim 1, wherein
the controller further includes a reference output storage configured to store a reference output of the first acoustic sensor disposed in the pipe in a state of no clogging, and
the controller is configured to determine the clogging of the pipe based on a difference of the first output and the reference output.

6. The semiconductor manufacturing apparatus according to claim 1, further comprising:
a second acoustic sensor; and
an alarm, wherein
the controller is configured to issue an alarm using the alarm based on the first output and a second output of the second acoustic sensor.

7. The semiconductor manufacturing apparatus according to claim 1, wherein
the first acoustic sensor is configured to measure a sound having a frequency of 100 kHz or more and 200 kHz or less.

8. The semiconductor manufacturing apparatus according to claim 1, further comprising:
a detoxifying device, wherein
the pipe is connected to the exhaust port and the detoxifying device.

9. The semiconductor manufacturing apparatus according to claim 1, further comprising:
a wafer processing number storage configured to store the number of wafers processed in the reaction chamber, wherein
the controller is further configured to determine the clogging based on the number.

10. The semiconductor manufacturing apparatus according to claim 1, further including a gas supply arranged to supply process gas to the reaction chamber.

11. The semiconductor manufacturing apparatus according to claim 1, further including:
a plurality of reaction chambers; and
a plurality of first acoustic sensors, each acoustic associated with a respective of the plurality of reaction chambers.

12. The semiconductor manufacturing apparatus according to claim 1, wherein the first acoustic sensor includes an acoustic emission sensor.

13. The semiconductor manufacturing apparatus according to claim 1, wherein the determining the clogging includes determining a material deposition amount on an inside of the pipe.

14. A control method for a semiconductor manufacturing apparatus, the semiconductor manufacturing apparatus comprising:
a reaction chamber;
a pipe connected to the reaction chamber;
a vacuum pump having an intake port and an exhaust port, and wherein the intake port or the exhaust port is connected to the pipe; and
a first acoustic sensor disposed in the pipe,
the control method comprising:
determining clogging of the pipe based on a first output of the first acoustic sensor.

15. The method according to claim 14, further comprising performing chemical vapor deposition in the reaction chamber.

16. The method according to claim 14, wherein
the clogging of the pipe is determined based on a threshold value.

17. The method according to claim 14, further comprising
converting the first output into a pipe clogging amount based on conversion information, and
controlling the clogging of the pipe based on the pipe clogging amount.

18. The method according to claim 17, wherein
the conversion information has a plurality of pieces of the conversion information used for each manufacturing process, and, the method further comprising determining which of the plurality of pieces of conversion information to use based on the manufacturing process.

19. The method according to claim 14, further comprising determining the clogging of the pipe based on a difference of the first output and a reference output of the first acoustic sensor disposed in the pipe in a state of no clogging.
